(19) United States
(12) Patent Application Publication
(10) Pub. No.: US 2010/0224936 A1
(43) Pub. Date: Sep. 9, 2010

(54) SEMICONDUCTOR DEVICE AND METHOD OF FABRICATING THE SAME

(75) Inventor: Akira Hokazono, Tokyo (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/683,037

(22) Filed: Jan. 6, 2010

(30) Foreign Application Priority Data
Mar. 3, 2009 (JP) 200949485

(51) Int. Cl. H01L 27/088; H01L 21/8234

(52) U.S. Cl. 257/368; 438/299; 257/E27.06; 257/E21.627

(57) ABSTRACT

A semiconductor device according to one embodiment includes: adjacent first and second transistors each formed on a semiconductor substrate, the first and second transistors respectively having first and second gate electrodes and sharing a source/drain region therebetween; a first insulating film formed on the first gate electrode; a second insulating film formed on the second gate electrode and comprising a region thicker than the first insulating film; and a self-aligned contact plug connected to the source/drain region, a horizontal distance from a center position of the self-aligned contact plug to the second gate electrode being less than a horizontal distance from a center position between the first and second gate electrodes to the second gate electrode.

### CROSS-REFERENCE TO RELATED APPLICATIONS

This application is based upon and claims the benefit of priority from prior Japanese Patent Application No. 2009-049485, filed on Mar. 3, 2009, the entire contents of which are incorporated herein by reference.

### BACKGROUND

A conventional semiconductor device is known in which a self-aligned contact plug is adopted and an alignment pitch of gate electrodes is narrowed for high integration. The semiconductor device, for example, is disclosed in a non-patent literary document of Y. Ishigaki et al., Symposium on VLSI Technology Digest of Technical Papers, 1994, pp. 99-100. Since the self-aligned contact plug is formed in self-aligned manner between two gate electrodes in a state of being insulated from these gate electrodes, the self-aligned contact plug does not short-circuit with the gate electrodes even if a portion thereof is on the gate electrodes.

### BRIEF SUMMARY

A semiconductor device according to one embodiment includes: adjacent first and second transistors each formed on a semiconductor substrate, the first and second transistors respectively having first and second gate electrodes and sharing a source/drain region therebetween; a first insulating film formed on the first gate electrode; a second insulating film formed on the second gate electrode and comprising a region thicker than the first insulating film; and a self-aligned contact plug connected to the source/drain region, a horizontal distance from a center position of the self-aligned contact plug to the second gate electrode being less than a horizontal distance from a center position between the first and second gate electrodes to the second gate electrode.

A semiconductor device according to another embodiment includes: adjacent first and second transistors each formed on a semiconductor substrate, the first and second transistors respectively having first and second gate electrodes and sharing a source/drain region therebetween; a self-aligned contact plug connected to the source/drain region; and first and second insulating films respectively formed on the first and second gate electrodes, the first and second insulating films each having a sidewall shape in which a thickness on the self-aligned contact plug side is thicker than that on the opposite side, and the first and second insulating films sandwiching the self-aligned contact plug.

A method of fabricating a semiconductor device according to another embodiment includes: forming adjacent first and second transistors on a semiconductor substrate, the first and second transistors respectively having first and second gate electrodes and sharing a source/drain region therebetween; forming a first interlayer insulating film between the first and second gate electrodes; forming a core above the first interlayer insulating film; forming sidewall insulating films on both sides of the core so as to cover the first and second gate electrodes; forming a second interlayer insulating film on the first interlayer insulating film and the sidewall insulating films; forming a contact hole in the first and second interlayer insulating films so as to pass between the sidewall insulating film on the first gate electrode and that on the second gate electrode and reach the source/drain region; and forming a self-aligned contact plug in the contact hole.

### BRIEF DESCRIPTION OF THE DRAWING

FIG. 1 is a cross sectional view of a semiconductor device according to a first embodiment;

FIGS. 2A to 2J are cross sectional views showing processes for fabricating the semiconductor device according to the first embodiment;

FIG. 3 is a cross sectional view of a semiconductor device according to a second embodiment;

FIGS. 4A to 4G are cross sectional views showing processes for fabricating the semiconductor device according to the second embodiment;

FIG. 5 is a cross sectional view of a semiconductor device according to a third embodiment;

FIGS. 6A and 6B are plan views schematically showing a structure of the semiconductor device according to the third embodiment and that of a semiconductor device as Comparative Example;

FIGS. 7A to 7C are cross sectional views showing processes for fabricating the semiconductor device according to the third embodiment;

FIG. 8 is a cross sectional view of a semiconductor device according to a fourth embodiment;

FIG. 9 is a plan view schematically showing a structure of the semiconductor device according to the fourth embodiment; and

FIGS. 10A to 10C are cross sectional views showing processes for fabricating the semiconductor device according to the fourth embodiment.

### DETAILED DESCRIPTION

### First Embodiment

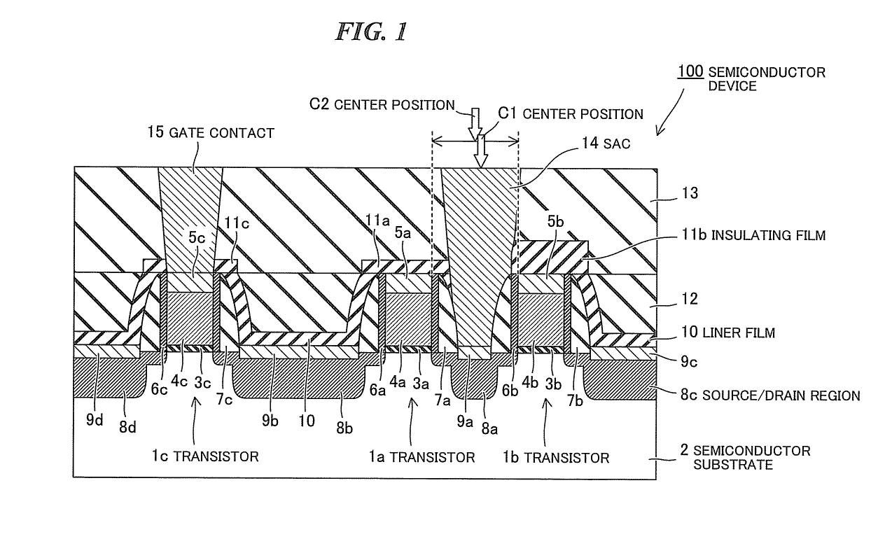

FIG. 1 is a cross sectional view of a semiconductor device 100 according to a first embodiment. The semiconductor device 100 contains transistors 1a, 1b and 1c formed on a semiconductor substrate 2, a liner film 10 covering side faces of the transistors 1a, 1b and 1c, insulating films 11a, 11b and 11c respectively covering the transistors 1a, 1b and 1c, interlayer insulating films 12 and 13 formed on the liner film 10 and the insulating films 11a, 11b and 11c, a self-aligned contact plug (hereinafter described as “SAC”) 14 and a gate contact 15.

The transistors 1a, 1b and 1c respectively have gate insulating films 3a, 3b and 3c, gate electrodes 4a, 4b and 4c, offset spacers 6a, 6b and 6c and gate sidewalls 7a, 7b and 7c. A source/drain region 8a is shared by the transistors 1a and 1b, a source/drain region 8b is shared by the transistors 1a and 1c, a source/drain region 8c belongs to the transistor 1b and a source/drain region 8d belongs to the transistor 1c.

The gate electrodes 4a, 4b and 4c have silicide layers 5a, 5b and 5c on respective upper portions or whole portions thereof. In addition, the source/drain region 8a, 8b, 8c and 8d have silicide layers 9a, 9b, 9c and 9d on respective upper portions thereof.

The SAC 14 connects the source/drain region 8a to a wiring thereabove (not shown). Meanwhile, the gate contact 15 connects the gate electrode 4c to a wiring thereabove (not shown).

In the present embodiment, since the transistors 1a and 1b are closely formed and a space between the gate electrodes 4a and 4b is narrow, the SAC 14 is used as a contact plug connected to the source/drain region 8a. The SAC is a contact plug formed in self-aligned manner after covering an upper surface of the gate electrode with an insulating cap film. In the present embodiment, the insulating films 11a and 11b are formed as insulating films which cover upper surfaces of the gate electrodes 4a and 4b.

Note that, a space between the transistor 1c is and other adjacent transistors, such as the transistor 1a adjacent to the transistor 1c, is larger than a space between the transistors 1a and 1b. Therefore, a normal contact plug which is not a SAC can be used as a contact plug (not shown) connected to the source/drain regions 8b and 8d.

At least a region of the insulating film 11b near the SAC 14 is thicker than the insulating films 11a and 11c. In addition, it is preferable that the insulating films 11a and 11c are made of the same material as the liner film 10 on the silicide layers 9a, 9b, 9c and 9d, and have a thickness substantially equal to that of the liner film 10 on the silicide layers 9a, 9b, 9c and 9d (e.g., 30-40 nm). This is because the insulating films 11a, 11c, and the liner film 10 on the silicide layers 9a, 9b, 9c and 9d are used as an etching stopper when contact holes, which is for contact plugs connected to the gate electrodes 4a, 4c and the source/drain region 8a, 8b, 8c and 8d, are formed in the interlayer insulating films 12 and 13.

However, in case that a formation position of a contact plug connected to the source/drain region 8a is shifted during the formation thereof and the contact plug is placed on the insulating film 11a, the thickness of the insulating film 11a is not sufficient for efficiently preventing short circuit between the contact plug and the gate electrode 4a. Thus, the SAC 14 is formed so as not to contact with a portion of the insulating film 11a located just above the gate electrode 4a.

Note that, in order to use the insulating film 11b as an etching stopper when a contact hole for a contact plug connected to the gate electrode 4b is formed in the interlayer insulating films 12 and 13, a thickness of a region of the insulating film 11b distant from the SAC 14 may be substantially same as that of the insulating films 11a and 11c.

On the other hand, the SAC 14 is formed so that a center position C1 thereof is intentionally located on the gate electrode 4b side from a center position C2 between the gate electrodes 4a and 4b, meaning that a horizontal distance from the center position C1 to the gate electrode 4b is less than a horizontal distance from the center position C2 to the gate electrode 4b. In other words, a distance between the center position C1 of the SAC 14 and the gate electrode 4b is closer than that between the center position C1 of the SAC 14 and the gate electrode 4a. This is because at least the region of the insulating film 11b near the SAC 14 is thicker than the insulating film 11a and it is possible to effectively suppress short circuit between the SAC 14 and the gate electrode 4a.

For example, when a pitch of the gate electrodes 4a and 4b is 90 nm and each gate electrode width is 25 nm, i.e., when a space between the gate electrodes 4a and 4b is 65 nm, a horizontal distance from the center position C1 of the SAC 14 to the center position C2 between the gate electrodes 4a and 4b is 3-5 nm.

Note that, since the gate electrode 4a is close to the gate electrode 4b (e.g., since a space between the gate electrodes 4a and 4b is 65 nm or less), it is difficult to simultaneously form the insulating films 11a and 11b by a normal method for patterning an insulating film due to a problem of lithography resolution, thus, the insulating films 11a and 11b are formed by different lithography processes. Thus, when both of the insulating films 11a and 11b are thickened, three lithography processes are required for respectively forming the insulating films 11a, 11b and 11c.

In the present embodiment, it is possible to form the insulating films 11a and 11c by one lithography process because the thickness of the insulating film 11a is substantially same as that of the insulating film 11c and the gate electrode 4a is not close to the gate electrode 4c. Thus, it is possible to form the insulating films 11a, 11b and 11c by two lithography processes.

The semiconductor substrate 2 is made of Si-based crystal such as Si crystal.

The gate insulating films 3a, 3b and 3c are made of, e.g., insulating material such as SiO₂, SiN or SiON or high-dielectric constant material such as HfSiON.

The gate electrodes 4a, 4b and 4c are made of, e.g., Si-based polycrystal such as polycrystalline silicon containing conductivity type impurities. In addition, the gate electrodes 4a, 4b and 4c may have a structure composed of a metal layer and a Si-based polycrystalline layer thereon.

In addition, the gate electrodes 4a, 4b and 4c may be a metal gate electrode made of metal such as W, Ta, Ti, Hf, Zr, Ru, Pt, Ir, Mo or Al, or a compound thereof. When the metal gate electrode is used, the silicide layers 5a, 5b and 5c are not formed.

The silicide layers 5a, 5b and 5c and the silicide layers 9a, 9b, 9c and 9d are made of metal silicide containing metal such as Ni, Co, Er, Pt or Pd.

The offset spacers 6a, 6b and 6c and the gate sidewalls 7a, 7b and 7c are made of insulating material such as SiO₂ or SiN. Alternatively, the gate sidewalls 7a, 7b and 7c may have a structure of two layer made of multiple types of insulating materials comprising SiN, SiO₂ or TEOS (Tetraethoxysilane), etc., furthermore, it may have a structure of three or more layers.

The source/drain region 8a, 8b, 8c and 8d contain conductivity type impurities. As or P, etc., is used as an n-conductivity type impurity, and B or BF₂, etc., is used as a p-conductivity type impurity.

The liner film 10 and the insulating films 11a, 11b and 11c are made of insulating material such as SiN.

The interlayer insulating films 12 and 13 are made of insulating material such as TEOS or BPSG (Boro-Phospho Silicate Glass). The interlayer insulating film 13 is, e.g., 50-60 nm in thickness.

The SAC 14 and the gate contact 15 are made of conductive material such as W or Cu.

An example of a method of fabricating a semiconductor device 100 according to the present embodiment will be described hereinafter.

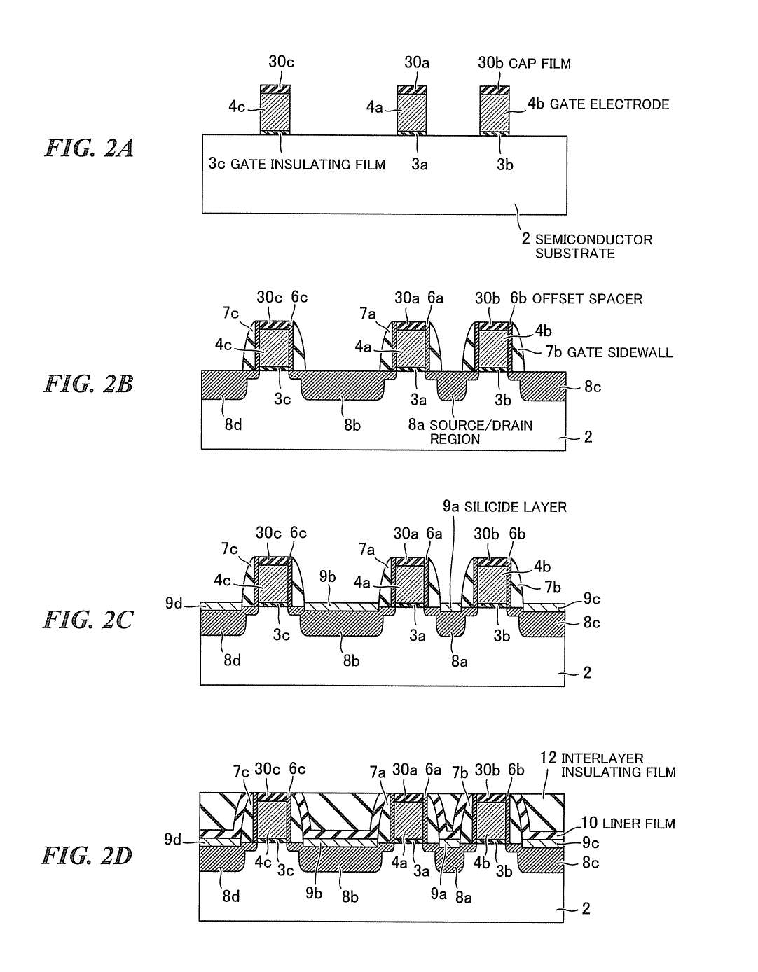

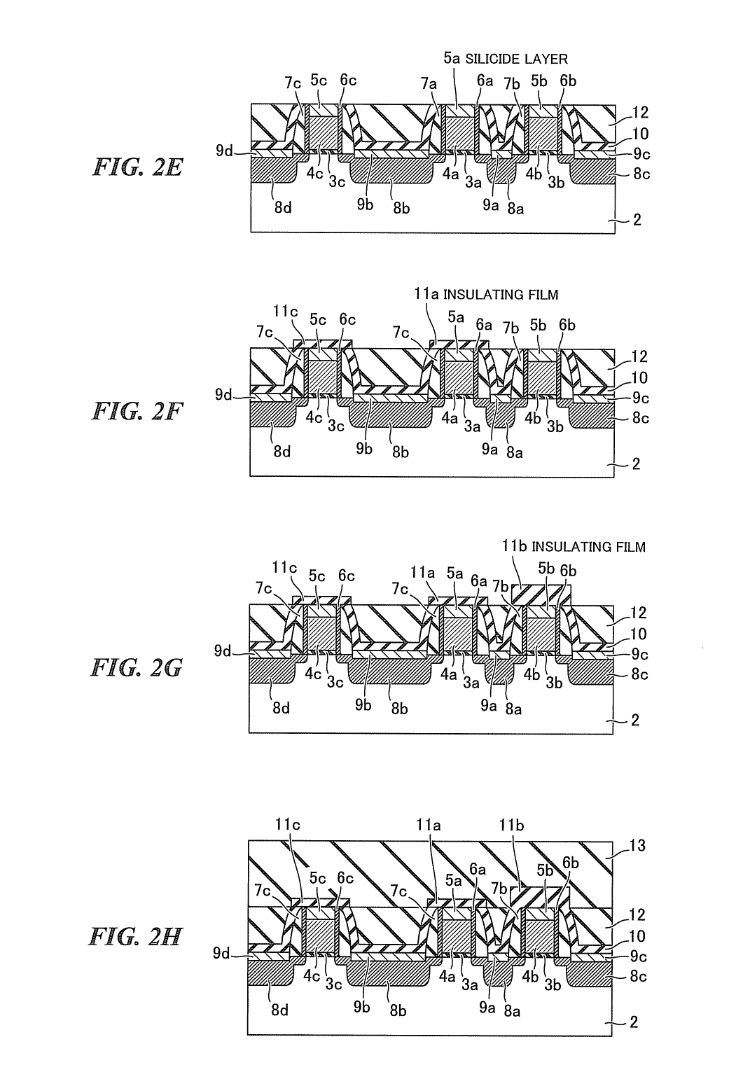

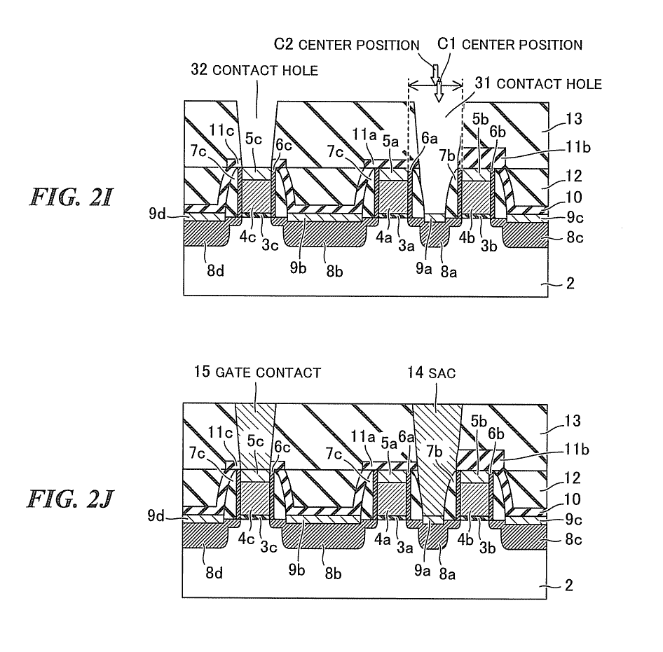

FIGS. 2A to 2J are cross sectional views showing processes for fabricating the semiconductor device 100 according to the first embodiment.

Firstly, although it is not shown in the figures, an element isolation region, a well and a channel region are formed in the semiconductor substrate 2. After that, heat treatment such as RTA (Rapid Thermal Annealing) is carried out for activating a conductivity type impurity in the well and the channel region.

Next, as shown in FIG. 2A, the gate insulating films 3a, 3b and 3c, the gate electrodes 4a, 4b and 4c and cap films 30a, 30b and 30c are formed in an element region on the semiconductor substrate 2.

An example of a specific method of forming these members will be described hereinafter. Firstly, a material film of the gate insulating films 3a, 3b and 3c such as a SiO₂ film is formed on the entire surface of the semiconductor substrate 2 by thermal oxidation method or LPCVD (Low-Pressure Chemical Vapor Deposition) method, etc., and then a material film of the gate electrodes 4a, 4b and 4c such as a polycrystalline Si film and a material film of the cap films 30a, 30b and 30c such as SiN are formed thereon by LPCVD method. Next, these laminated material films are patterned by, e.g., a combination of optical lithography method such as X-ray lithography method or electron beam lithography method with RIE (Reactive Ion Etching) method for shaping into the gate insulating films 3a, 3b and 3c, the gate electrodes 4a, 4b and 4c and the cap films 30a, 30b and 30c.

Note that, since the pattern of the gate electrode 4a is close to that of the gate electrode 4b, these patterns may be formed using sidewall pattern transfer process, etc.

Next, as shown in FIG. 2B, the offset spacers 6a, 6b and 6c, the gate sidewalls 7a, 7b and 7c and the source/drain region 8a, 8b, 8c and 8d are formed.

An example of a specific method of forming these members will be described hereinafter. Firstly, after a 1-2 nm thick SiO₂ film (not shown) is formed on the surfaces of the gate electrodes 4a, 4b and 4c by thermal oxidation method, a material film (not shown) of the offset spacers 6a, 6b and 6c such as a 3-12 nm thick SiO₂ film is formed thereon by LPCVD method. Next, the material film of the offset spacers 6a, 6b and 6c is shaped into the offset spacers 6a, 6b and 6c by RIE method.

Next, conductivity type impurities are implanted into the entire surface of the semiconductor substrate 2 by ion implantation procedure using the offset spacers 6a, 6b and 6c and the cap films 30a, 30b and 30c as a mask, which results in that the shallow regions of the source/drain regions 8a, 8b, 8c and 8d are formed. Furthermore, heat treatment such as spike annealing is carried out for activating the implanted conductivity type impurities.

Here, when n-type source/drain regions 8a, 8b, 8c and 8d are formed, for example, halo regions are formed by implanting BF₂ under a condition at an implantation energy of 20 KeV, an implantation dose of 3.0×10¹³ cm⁻² and an implantation angle of 30° (an angle with reference to a direction vertical to the surface of the semiconductor substrate 2), subsequently, the shallow regions of the source/drain regions 8a, 8b, 8c and 8d are formed by implanting As under a condition at an implantation energy of 1-5 KeV and an implantation dose of 5.0×10¹⁴ to 1.5×10¹⁵ cm⁻².

Meanwhile, when p-type source/drain regions 8a, 8b, 8c and 8d are formed, for example, halo regions are formed by implanting As under a condition at an implantation energy of 40 KeV, an implantation dose of 3.0×10¹³ cm⁻² and an implantation angle of 30° (an angle with reference to a direction vertical to the surface of the semiconductor substrate 2), subsequently, the shallow regions of the source/drain regions 8a, 8b, 8c and 8d are formed by implanting BF₂ under a condition at an implantation energy of 1-3 KeV and an implantation dose of 5.0×10¹⁴ to 1.5×10¹⁵ cm⁻², or by implanting B.

Next, a material film of the gate sidewalls 7a, 7b and 7c such as SiO₂ is formed on the entire surface of the semiconductor substrate 2 by LPCVD method, and is shaped into the gate sidewalls 7a, 7b and 7c by RIE method.

Next, conductivity type impurities are implanted into the entire surface of the semiconductor substrate 2 by ion implantation procedure using the gate sidewalls 7a, 7b and 7c and the cap films 30a, 30b and 30c as a mask, which results in that deep high-concentration regions of the source/drain regions 8a, 8b, 8c and 8d are formed. Furthermore, heat treatment such as spike annealing is carried out for activating the implanted conductivity type impurities.

Here, when n-type source/drain regions 8a, 8b, 8c and 8d are formed, for example, the deep high-concentration regions of the source/drain regions 8a, 8b, 8c and 8d are formed by implanting AS under a condition at an implantation energy of 15-25 KeV and an implantation dose of 2.0×10¹⁵ to 4.0×10¹⁵ cm⁻².

Meanwhile, when p-type source/drain regions 8a, 8b, 8c and 8d are formed, for example, the deep high-concentration regions of the source/drain regions 8a, 8b, 8c and 8d are formed by implanting B under a condition at an implantation energy of 1.5-3.5 KeV and an implantation dose of 2.0×10¹⁵ to 4.0×10¹⁵ cm⁻².

Alternatively, before the process for forming the deep high-concentration regions of the source/drain regions 8a, 8b, 8c and 8d, an elevated source drain structure may be formed by selectively epitaxially growing Si crystals or SiGe crystals using exposed regions in the upper surface of the semiconductor substrate 2 as a base.

Next, as shown in FIG. 2C, the silicide layers 9a, 9b, 9c and 9d are formed on regions of the semiconductor substrate 2 where the source/drain regions 8a, 8b, 8c and 8d are formed therein.

An example of a method of forming the silicide layers 9a, 9b, 9c and 9d made of Ni silicide will be described hereinafter. Firstly, a natural oxide film in an exposed region of the semiconductor substrate 2 is removed by hydrofluoric acid treatment. Next, after forming a Ni film on the entire surface of the semiconductor substrate 2 by sputtering method, etc., silicidation reaction is generated between the Ni film and the semiconductor substrate 2 by heat treatment such as RTA, etc., under the temperature condition of 400-500° C., which results in that the silicide layers 9a, 9b, 9c and 9d are formed. Note that, since the cap films 30a, 30b and 30c are formed on the gate electrodes 4a, 4b and 4c, the gate electrodes 4a, 4b and 4c do not react with the Ni film. Next, an unreacted portion of the Ni film is removed using a mixed solution of sulfuric acid and hydrogen peroxide solution, etc.

Note that, when the Ni silicide is formed, a process in which a Ni film is formed and a TiN film is subsequently formed thereon, or, a process in which a Ni film is formed and is etched using a mixed solution of sulfuric acid and hydrogen peroxide solution after carrying out the low temperature RTA at 250-400° C. once and then the RTA is carried out again at 400-550° C. for reducing sheet resistance (two step annealing), may be carried out. In addition, Pt may be added to the Ni film.

Next, as shown in FIG. 2D, the liner film 10 and the interlayer insulating film 12 are formed.

An example of a specific method of forming these members will be described hereinafter. Firstly, a material film of the liner film 10 such as a SiN film and a material film of the interlayer insulating film 12 such as a TEOS film are formed on the entire surface of the semiconductor substrate 2 by CVD method, etc. Next, the material film of the liner film 10 and that of the interlayer insulating film 12 is subjected to planarizing treatment such as CMP (Chemical Mechanical Polishing) using the cap films 30a, 30b and 30c as a stopper, which results in that the liner film 10 and the interlayer insulating film 12 are formed.

Next, as shown in FIG. 2E, after removing the cap films 30a, 30b and 30c, the silicide layers 5a, 5b and 5c are formed respectively on the gate electrodes 4a, 4b and 4c.

An example of a specific method of forming these members will be described hereinafter. Firstly, when the cap films 30a, 30b and 30c are made of a SiN film, the cap films 30a, 30b and 30c are removed using phosphoric acid at about 170° C. Next, after forming a metal film by sputtering method, etc., so as to cover upper surfaces of the gate electrodes 4a, 4b and 4c, silicidation reaction is generated between the metal film and the gate electrodes 4a, 4b, 4c by heat treatment, which results in that the silicide layers 5a, 5b and 5c are formed.

Alternatively, the silicide layers 5a, 5b and 5c may be made of metal silicide different from that of the silicide layers 9a, 9b, 9c and 9d, and metal silicide having smaller electric resistance than that of the silicide layers 9a, 9b, 9c and 9d can be used as metal silicide composing the silicide layers 5a, 5b and 5c.

Next, as shown in FIG. 2F, the insulating films 11a and 11c are respectively formed on the silicide layers 5a and 5c.

In detail, for example, a material film of the insulating films 11a and 11c is formed on the entire surface of the semiconductor substrate 2 by CVD method, etc., and then is subsequently patterned by a combination of lithography method and RIE method for shaping into the insulating films 11a and 11c.

Next, as shown in FIG. 2G, the insulating film 11b is formed on the silicide layer 5b.

In detail, for example, a material film of the insulating film 11b is formed on the entire surface of the semiconductor substrate 2 by a CVD method, etc., and then is subsequently patterned by a combination of lithography method and RIE method for shaping into the insulating film 11b. Here, the material film of the insulating film 11b is formed thicker than that of the insulating films 11a and 11c.

Note that, when the liner film 10 is formed in a thickness nearly equal to the insulating film 11b and portions thereof on the cap films 30a, 30b and 30c are left and used instead of the insulating films 11a, 11b and 11c without being removed by planarizing treatment shown in FIG. 2D, although it is possible to suppress a short circuit between the gate electrodes 4a, 4b and the SAC 14, it is not possible to form the silicide layers 5a, 5b and 5c. In this case, it is difficult to use the gate electrodes 4a, 4b and 4c for a circuit which requires high-speed operation, such as a Logic LSI.

Next, as shown in FIG. 2H, the interlayer insulating film 13 is formed on the insulating films 11a, 11b, 11c and the interlayer insulating film 12 by CVD method, etc.

Next, as shown in FIG. 2I, a contact hole 31 for forming the SAC 14 and a contact hole 32 for forming the gate contact 15 are formed.

In detail, the interlayer insulating films 12 and 13 are patterned by a combination of the lithography method and the RIE method, which results in that the contact holes 31 and 32 are formed. Here, a center position C1 of the pattern of the contact hole 31 (which coincides with the center position C1 of the SAC 14) is located on the gate electrode 4b side from the center position C2 between the gate electrodes 4a and 4b. In addition, at this time, the insulating film 11c and the liner film 10 on the silicide layer 9a function as an etching stopper.

In addition, by preliminarily forming the silicide layer 5c relatively thick, it is possible to prevent the silicide layer 5c from disappearing due to over-etching when forming the contact hole 32. Furthermore, by preliminarily forming the silicide layer 5c relatively thick, it is possible to decrease sheet resistance of the silicide layer 5c.

Next, as shown in FIG. 2J, the SAC 14 and the gate contact 15 are respectively formed in the contact holes 31 and 32.

An example of a specific method of forming the SAC 14 and the gate contact 15 will be described hereinafter. Firstly, a material film of the SAC 14 and the gate contact 15 such as W is formed so as to fill the contact holes 31 and 32. Next, a portion of the material film outside of the contact holes 31 and 32 is removed by planarizing treatment, etc., for shaping into the SAC 14 and the gate contact 15.

### Effect of the First Embodiment

According to the first embodiment, a thick region is formed only in the insulating film 11b between the insulating films 11a and 11b and the SAC 14 is formed so that the center position C1 thereof is located on the gate electrode 4b side from the center position C2 between the gate electrodes 4a and 4b, hence, it is possible to suppress the short circuit between the SAC 14 and the gate electrodes 4a, 4b while suppressing the number of lithography processes and the cost for fabricating the semiconductor device 100.

### Second Embodiment

The second embodiment is different from the first embodiment in that sidewall insulating films 16a and 16b formed by a sidewall pattern transfer process are used instead of the insulating films 11a and 11b. Note that, the explanation will be omitted or simplified for the same points as the first embodiment.

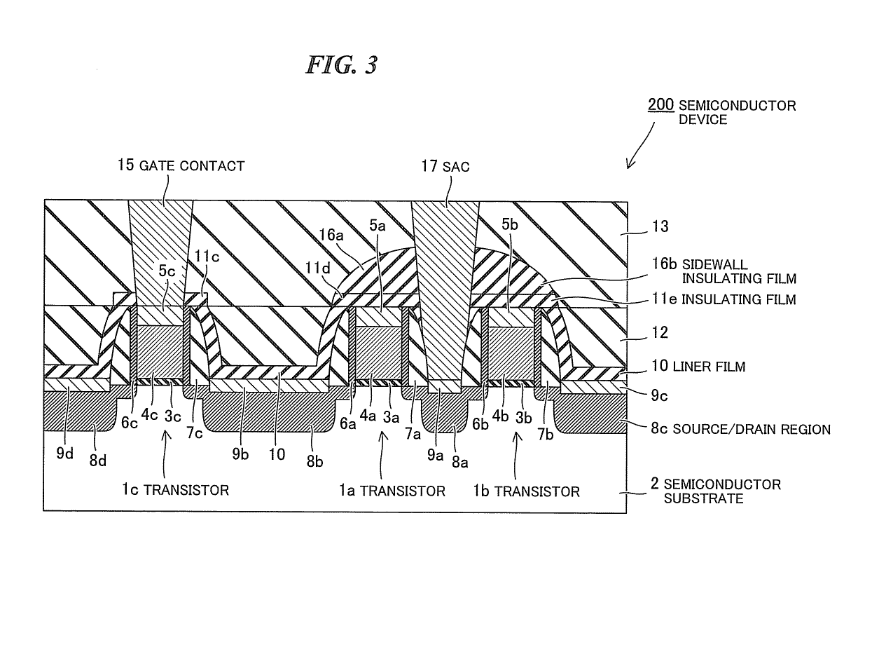

FIG. 3 is a cross sectional view of a semiconductor device 200 according to a second embodiment. The semiconductor device 200 contains transistors 1a, 1b and 1c formed on a semiconductor substrate 2, a liner film 10 covering side faces of the transistors 1a, 1b and 1c, insulating films 11d, 11e and 11c respectively covering the transistors 1a, 1b and 1c, the sidewall insulating films 16a and 16b formed on the insulating films 11d and 11e, interlayer insulating films 12 and 13, a SAC 17 and a gate contact 15.

The SAC 17 connects the source/drain region 8a to a wiring thereabove (not shown). Meanwhile, the gate contact 15 connects the gate electrode 4c to a wiring thereabove (not shown). In addition, the SAC 17 and the gate contact 15 are made of conductive material such as W or Cu.

The sidewall insulating films 16a and 16b are formed by a sidewall pattern transfer process. Thus, even when the gate electrode 4a is close to the gate electrode 4b and insulating cap films on the gate electrodes 4a and 4b, which are necessary for forming the SAC 17, are difficult to be formed, the sidewall insulating films 16a and 16b can be formed as a cap film having a sufficient thickness for suppressing the short circuit between the gate electrodes 4a, 4b and the SAC 17. In the present embodiment, laminated bodies of the insulating films 11d, 11e and the sidewall insulating films 16a, 16b function as a sidewall-shaped cap film on the gate electrodes 4a and 4b. In addition, since the sidewall insulating films 16a and 16b are formed by a sidewall pattern transfer process, the thickness thereof is thicker on the SAC 17 side than on the opposite side thereof (a side distant from the SAC 17). Thus, the thickness of the laminated bodies of the insulating films 11d, 11e and the sidewall insulating films 16a, 16b is also thicker on the SAC 17 side than on the opposite side (a side distant from the SAC 17).

The sidewall insulating films 16a and 16b are made of insulating material such as SiN. In addition, the sidewall insulating films 16a, 16b and the insulating films 11d, 11e preferably have a width larger than gate lengths of the gate electrodes 4a and 4b so as to completely cover the gate electrodes 4a and 4b. The widths of the sidewall insulating films 16a and 16b are, e.g., about 20 nm larger than the gate lengths of the gate electrodes 4a and 4b.

An example of a method of fabricating a semiconductor device 200 according to the present embodiment will be described hereinafter.

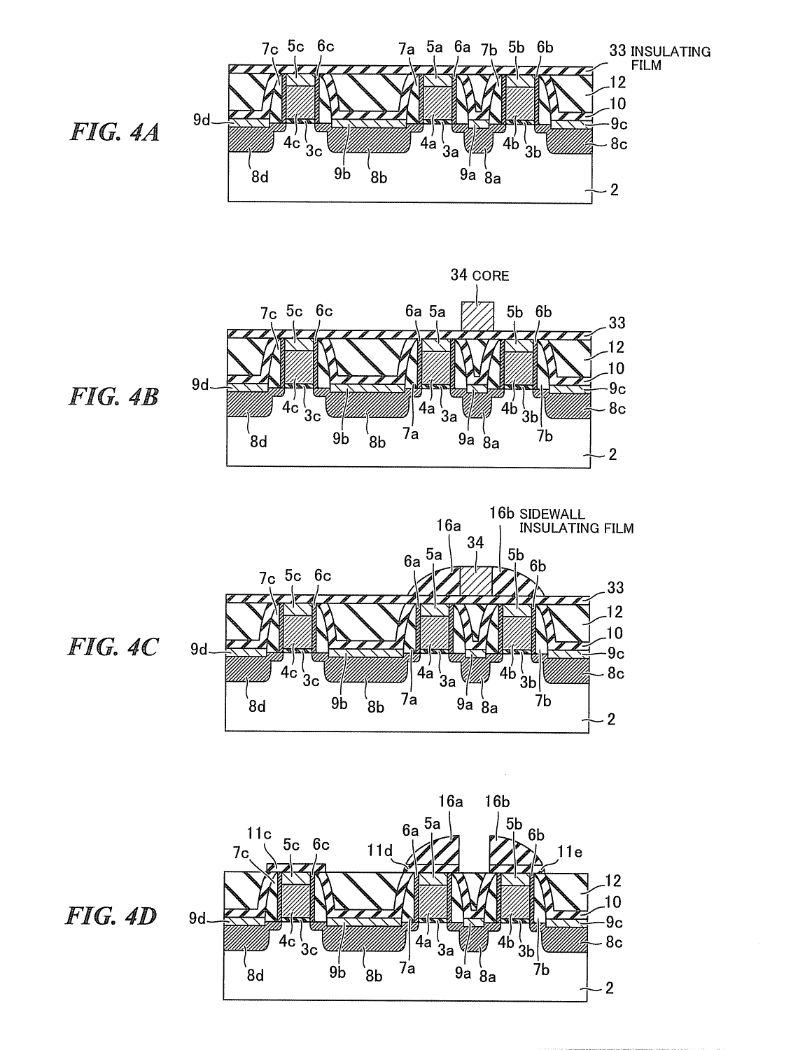

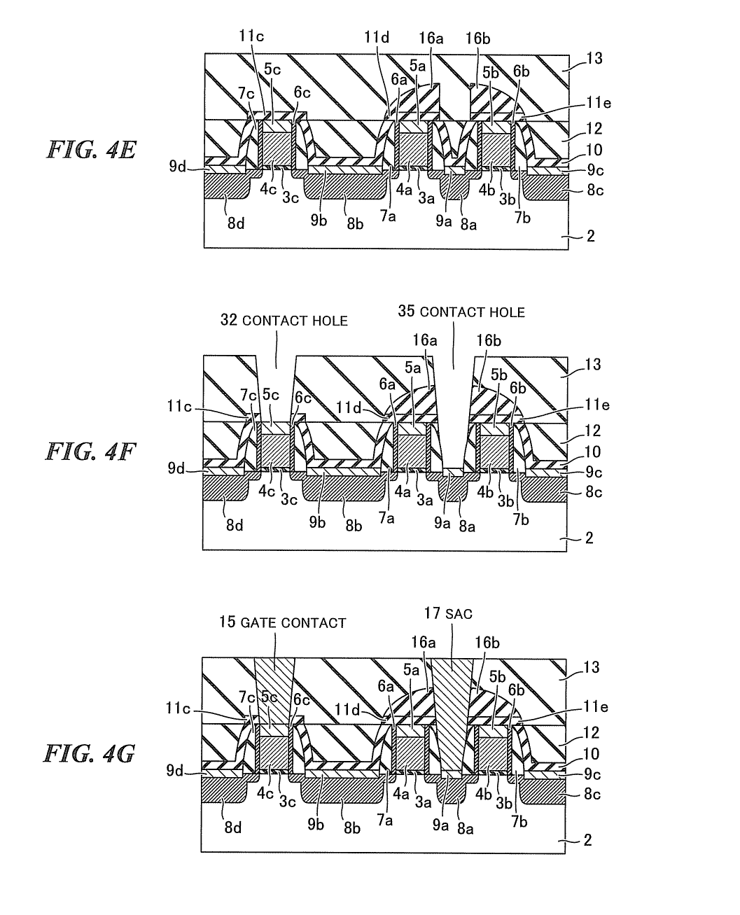

FIGS. 4A to 4G are cross sectional views showing processes for fabricating the semiconductor device 200 according to the second embodiment.

Firstly, the processes, shown in FIGS. 2A to 2E, until the process for forming the silicide layers 5a, 5b and 5c are carried out in the same way as the first embodiment.

Next, as shown in FIG. 4A, an insulating film 33 is formed on the silicide layers 5a, 5b, 5c and the planarized interlayer insulating film 12 by CVD method, etc.

Next, as shown in FIG. 4B, a core 34 for the sidewall pattern transfer process is formed in a region on the insulating film 33 between the gate electrodes 4a and 4b.

In detail, for example, a material film of the core 34 such as TEOS is formed on the entire surface of the insulating film 33 by a CVD method, etc., and then is subsequently patterned by a combination of lithography method and RIE method for shaping into the core 34.

Next, as shown in FIG. 4C, the sidewall insulating films 16a and 16b are formed on side faces of the core 34.

In detail, for example, a material film of the sidewall insulating films 16a and 16b such as SiN is formed on the entire surface of the semiconductor substrate 2 by CVD method, and is shaped into the sidewall insulating films 16a and 16b by RIE method.

Next, as shown in FIG. 4D, after removing the core 34 by hydrofluoric acid, etc., the insulating film 33 is patterned, which results in that the insulating films 11c, 11d and 11e are formed.

In detail, for example, after forming a photoresist having a pattern of the insulating film 11c by lithography method, the insulating film 33 is etched by RIE method using the photoresist and the sidewall insulating films 16a, 16b as a mask, and is shaped into the insulating films 11c, 11d and 11e.

Next, as shown in FIG. 4E, the interlayer insulating film 13 is formed on the insulating film 11c, the sidewall insulating films 16a, 16b and the interlayer insulating film 12 by CVD method, etc.

Next, as shown in FIG. 4F, a contact hole 35 for forming the SAC 17 and a contact hole 32 for forming the gate contact 15 are formed.

Next, as shown in FIG. 4G, the SAC 17 and the gate contact 15 are respectively formed in the contact holes 35 and 32.

At this time, when the contact hole 35 is formed being shifted from the center portion between the gate electrodes 4a and 4b, the position of the SAC 17 is also shifted from the center portion between the gate electrodes 4a and 4b. However, since the both of the sidewall insulating films 16a and 16b have a sufficient thickness, it is possible to suppress the short circuit between the SAC 17 and the gate electrodes 4a, 4b.

### Effect of the Second Embodiment

According to the second embodiment, by forming the sidewall insulating films 16a and 16b using the sidewall pattern transfer process, it is possible to suppress the short circuit between the SAC 17 and the gate electrodes 4a, 4b while suppressing the number of lithography processes and the cost for fabricating the semiconductor device 200.

### Third Embodiment

The third embodiment is different from the first embodiment in that a local interconnect (hereinafter described as “LI”) 18 is used instead of the SAC 14. Note that, the explanation will be omitted or simplified for the same points as the first embodiment.

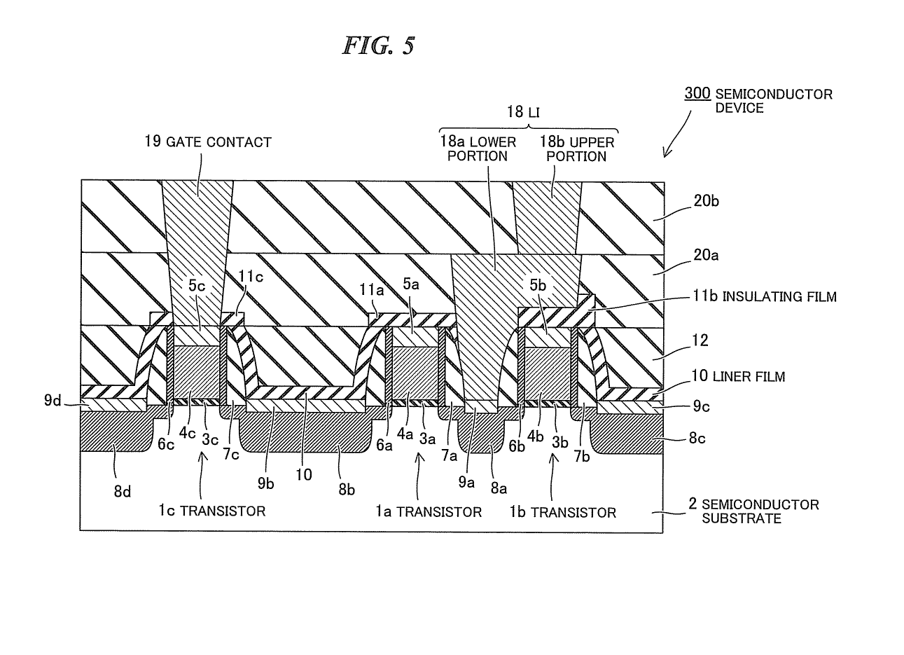

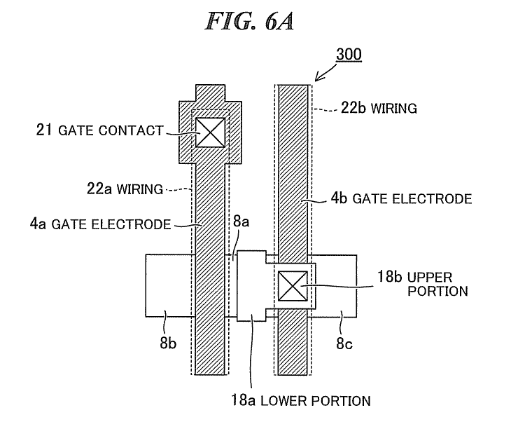

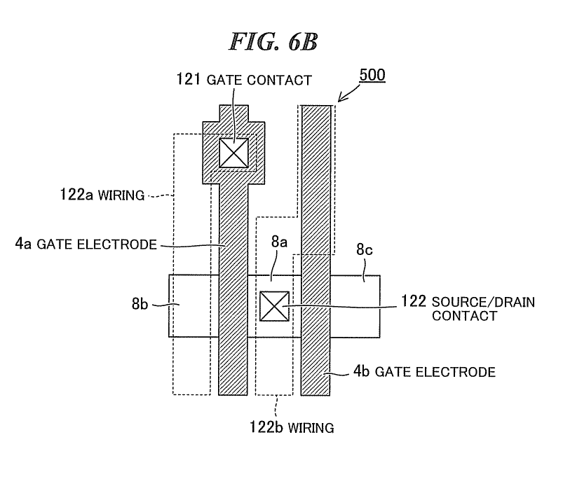

FIG. 5 is a cross sectional view of a semiconductor device 300 according to a third embodiment. In addition, FIG. 6A is a plan view schematically showing a structure of the semiconductor device 300 according to the third embodiment.

The semiconductor device 300 contains transistors 1a, 1b and 1c formed on a semiconductor substrate 2, a liner film 10 covering side faces of the transistors 1a, 1b and 1c, insulating films 11a, 11b and 11c respectively covering the transistors 1a, 1b and 1c, interlayer insulating films 12, 20a and 20b formed on the liner film 10 and the insulating films 11a, 11b and 11c, a LI 18 and a gate contact 19.

The LI 18 connects the source/drain region 8a to a wiring 22b thereabove. Meanwhile, the gate contact 19 connects the gate electrode 4c to a wiring thereabove (not shown). In addition, the LI 18 and the gate contact 19 are made of conductive material such as W or Cu. In addition, the semiconductor device 300 has a gate contact 21 for connecting the gate electrode 4a to a wiring 22a thereabove.

The LI 18 contains a lower portion 18a and an upper portion 18b. The lower portion 18a is a self-aligned contact plug which is formed in self-aligned manner between the gate electrodes 4a and 4b. In addition, a portion of the lower portion 18a is located above the gate electrode 4b via the insulating film 11b. Thus, a center position of the lower portion 18a is located on the gate electrode 4b side from the center position between the gate electrodes 4a and 4b.

The upper portion 18b is formed on a region in the lower portion 18a located above the gate electrode 4b, and the wiring 22b is formed on the upper portion 18b. Thus, as shown in FIG. 6A, it is possible to form the wiring 22b above the gate electrode 4b.

FIG. 6B is a plan view schematically showing a structure of a semiconductor device 500 as Comparative Example. The semiconductor device 500 has a source/drain contact 122 having a normal shape, instead of having the LI 18 in the present embodiment. The source/drain contact 122 connects the source/drain region 8a to an upper wiring 122b. In addition, a gate contact 121 connects the gate electrode 4a to an upper wiring 122a.

According to the structure of the semiconductor device 500, when the wirings 122a and 122b are formed in a linear pattern parallel to the gate electrodes 4a and 4b, a space between the wirings 122a and 122b becomes too narrow, thus, there is a problem in voltage endurance characteristics or leak-resistant characteristics between the wirings 122a and 122b. Thus, the wirings 122a and 122b are formed in patterns which are bent as shown in FIG. 6B in order to ensure sufficient space therebetween. Since the wirings 122a and 122b have a bent pattern, there is a portion where a design matching the pitch is difficult to be formed, and it is thus difficult to increase the integration degree of the circuit.

On the other hand, according to the third embodiment, since a contact portion of the LI 18 with the wiring 22b is located above the gate electrode 4b, it is possible to form the wirings 22a and 22b in a linear pattern parallel to the gate electrodes 4a and 4b while ensuring voltage endurance characteristics or leak-resistant characteristics.

At least a region of the insulating film 11b between the lower portion 18a and the gate electrode 4b is thicker than the insulating film 11a. Therefore, it is possible to effectively suppress a short circuit between the lower portion 18a of the LI 18 and the gate electrode 4b.

The liner film 10 and the insulating films 11a, 11b and 11c are made of insulating material such as SiN.

The interlayer insulating films 12, 20a and 20b are made of insulating material such as TEOS or BPSG.

An example of a method of fabricating a semiconductor device 300 according to the present embodiment will be described hereinafter.

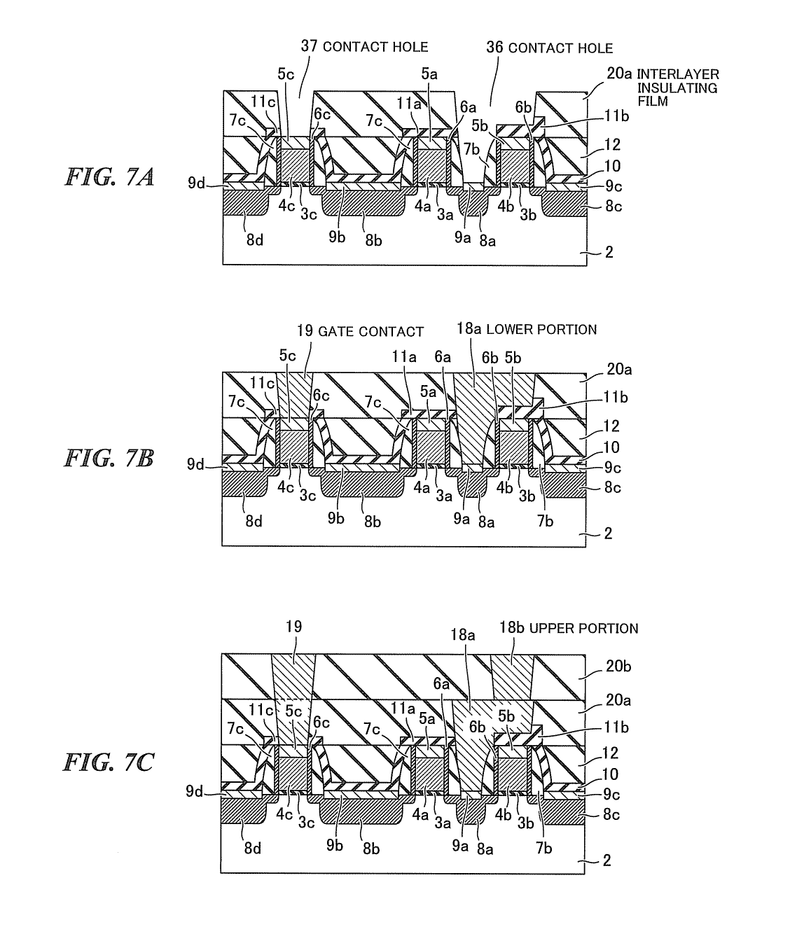

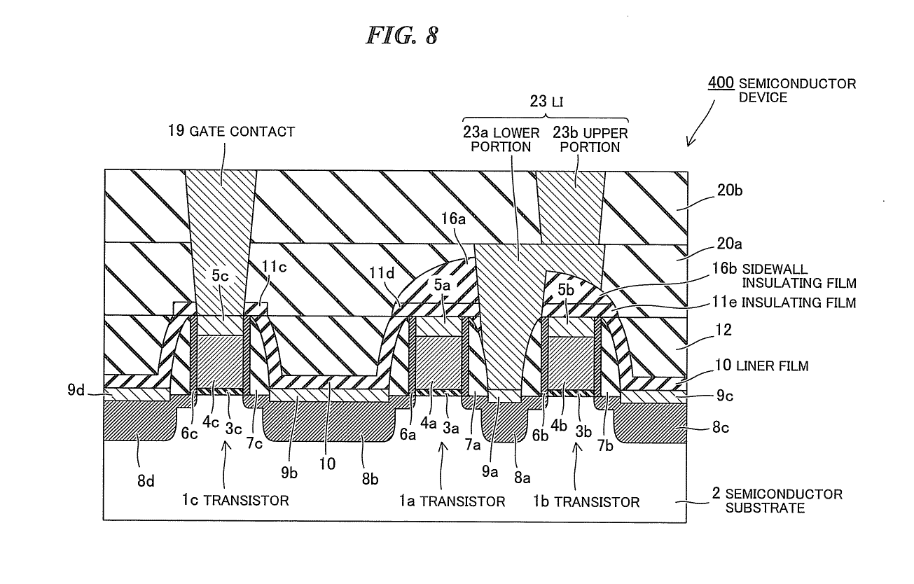

FIGS. 7A to 7C are cross sectional views showing processes for fabricating the semiconductor device 300 according to the third embodiment.

Firstly, the processes, shown in FIGS. 2A to 2G, until the process for forming the insulating film 11b are carried out in the same way as the first embodiment. After that, the interlayer insulating film 20a is formed instead of the interlayer insulating film 13.

Next, as shown in FIG. 7A, a contact hole 36 for forming the lower portion 18a of the LI 18 and a contact hole 37 above the gate electrode 4c are formed in the interlayer insulating films 12 and 20a.

In detail, the interlayer insulating films 12 and 20a are patterned by a combination of the lithography method and the RIE method, which results in that the contact holes 36 and 37 are formed. At this time, the insulating film 11b and the liner film 10 on the silicide layer 9a function as an etching stopper. Note that, although the insulating film 11b is etched and thinned by etching at the time of forming the contact holes 36 and 37, a region of the etched insulating film 11b between the contact hole 36 and the gate electrode 4b is sufficiently thick for preventing the short circuit between the LI 18 and the gate electrode 4b.

Next, as shown in FIG. 7B, the lower portion 18a of the LI 18 and a lower portion of the gate contact 19 are respectively formed in the contact holes 36 and 37.

An example of a specific method of forming the lower portion 18a will be described hereinafter. Firstly, a material film of the lower portion 18a and the lower portion of the gate contact 19 such as W is formed so as to fill the contact holes 36 and 37. Next, a portion of the material film outside of the contact holes 36 and 37 is removed by planarizing treatment, etc., for shaping into the lower portion 18a and the lower portion of the gate contact 19.

Next, as shown in FIG. 7C, the interlayer insulating film 20b, the upper portion 18b and an upper portion of the gate contact 19 are formed.

An example of a specific method of forming these members will be described hereinafter. Firstly, the interlayer insulating film 20b is formed on the interlayer insulating film 20a using the CVD method, etc. Next, interlayer insulating film 20b is patterned by a combination of the lithography method and the RIE method, which results in that a contact hole for the upper portion 18b and that for the upper portion of the gate contact 19 are formed. Next, a material film of the upper portion 18b and the upper portion of the gate contact 19 such as W is formed so as to fill the contact holes. Next, a portion of the material film outside of the contact holes is removed by planarizing treatment, etc., for shaping into the upper portion 18b and the upper portion of the gate contact 19.

### Effect of the Third Embodiment

According to the third embodiment, when the local interconnect is formed for improving the integration degree of the circuit, a thick region is formed only in the insulating film 11b between the insulating films 11a and 11b and the lower portion 18a of the LI 18 is formed on the thick region of the insulating film 11b, hence, it is possible to suppress the short circuit between the LI 18 and the gate electrode 4b while suppressing the number of lithography processes and the cost for fabricating the semiconductor device 300.

### Fourth Embodiment

The fourth embodiment is different from the second embodiment in that a LI 23 is used instead of the SAC 17. Note that, the explanation will be omitted or simplified for the same points as the second embodiment.

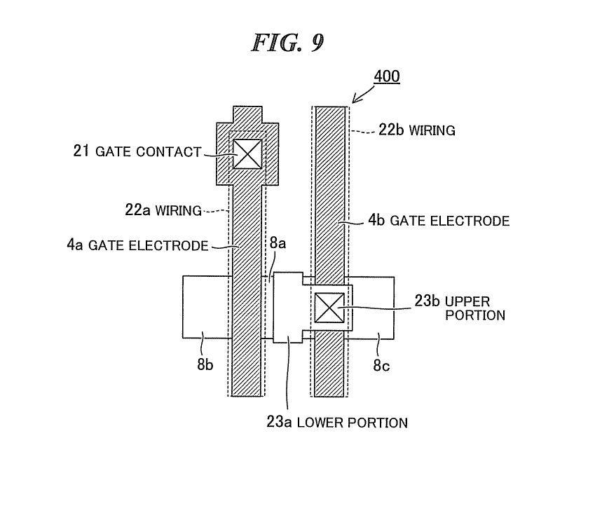

FIG. 8 is a cross sectional view of a semiconductor device 400 according to a fourth embodiment. In addition, FIG. 9 is a plan view schematically showing a structure of the semiconductor device 400.

The semiconductor device 400 contains transistors 1a, 1b and 1c formed on a semiconductor substrate 2, a liner film 10 covering side faces of the transistors 1a, 1b and 1c, insulating films 11c, 11d and 11e respectively covering the transistors 1a, 1b and 1c, sidewall insulating films 16a and 16b formed on the insulating films 11d and 11e, interlayer insulating films 12, 20a and 20b, a LI 23 and a gate contact 19.

The sidewall insulating films 16a and 16b are formed by a sidewall pattern transfer process. Thus, the thickness of the sidewall insulating films 16a and 16b is thicker on the SAC 17 side than on the opposite side thereof. In addition, the sidewall insulating films 16a and 16b are made of an insulating material such as SiN. In addition, the sidewall insulating films 16a and 16b preferably have a width larger than gate lengths of the gate electrodes 4a and 4b in order to completely cover the gate electrodes 4a and 4b.

The LI 23 connects the source/drain region 8a to a wiring 22a thereabove. Meanwhile, the gate contact 19 connects the gate electrode 4c and a wiring thereabove (not shown). In addition, the LI 23 and the gate contact 19 are made of conductive material such as W or Cu.

The LI 23 contains a lower portion 23a and an upper portion 23b. The lower portion 23a is a self-aligned contact plug which is formed in self-aligned manner between the gate electrodes 4a and 4b. In addition, a portion of the lower portion 23a is located above the gate electrode 4b via the sidewall insulating film 16b.

The upper portion 23b is formed on a region in the lower portion 23a located above the gate electrode 4b, and the wiring 22b is formed on the upper portion 23b. Thus, it is possible to form the wiring 22b above the gate electrode 4b.

Since a contact portion of the LI 23 with the wiring 22b is located above the gate electrode 4b, it is possible to form the wirings 22a and 22b in a linear pattern parallel to the gate electrodes 4a and 4b while ensuring voltage endurance characteristics or leak-resistant characteristics.

The interlayer insulating films 12, 20a and 20b are made of insulating material such as TEOS or BPSG.

An example of a method of fabricating a semiconductor device 400 according to the present embodiment will be described hereinafter.

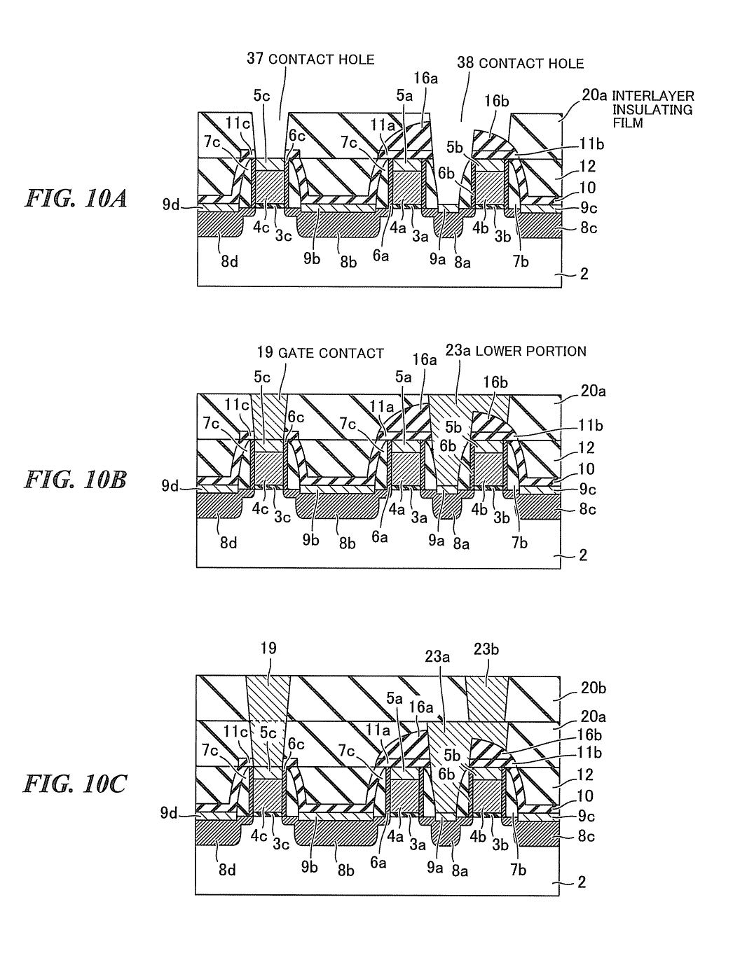

FIGS. 10A to 10C are cross sectional views showing processes for fabricating the semiconductor device 400 according to the fourth embodiment.

Firstly, the processes, shown in FIGS. 4A to 4D, until the process for forming the insulating films 11c, 11d and 11e are carried out in the same way as the second embodiment. After that, the interlayer insulating film 20a is formed instead of the interlayer insulating film 13.

Next, as shown in FIG. 10A, a contact hole 38 for forming the lower portion 23a of the LI 23 and a contact hole 37 above the gate electrode 4c are formed in the interlayer insulating films 12 and 20a.

In detail, the interlayer insulating films 20a and 12 are patterned by a combination of the lithography method and the RIE method, which results in that the contact holes 37 and 38 are formed. At this time, the sidewall insulating film 16b and the liner film 10 on the silicide layer 9a function as an etching stopper. Note that, although the sidewall insulating film 16b is etched and thinned by etching at the time of forming the contact holes 37 and 38, a region of the etched sidewall insulating film 16b between the contact hole 38 and the gate electrode 4b is sufficiently thick for preventing the short circuit between the LI 23 and the gate electrode 4b.

Next, as shown in FIG. 10B, the lower portion 23a of the LI 23 and a lower portion of the gate contact 19 are respectively formed in the contact holes 37 and 38.

An example of a specific method of forming the lower portion 23a will be described hereinafter. Firstly, a material film of the lower portion 23a and the lower portion of the gate contact 19 such as W is formed so as to fill the contact holes 37 and 38. Next, a portion of the material film outside of the contact holes 37 and 38 is removed by planarizing treatment, etc., for shaping into the lower portion 23a and the lower portion of the gate contact 19.

Next, as shown in FIG. 10C, the interlayer insulating film 20b, the upper portion 23b and an upper portion of the gate contact 19 are formed.

An example of a specific method of forming these members will be described hereinafter. Firstly, the interlayer insulating film 20b is formed on the interlayer insulating film 20a using the CVD method, etc. Next, interlayer insulating films 20a and 20b are patterned by a combination of the lithography method and the RIE method, which results in that a contact hole for the upper portion 23b and that for the upper portion of the gate contact 19 are formed. Next, a material film of the upper portion 23b and the upper portion of the gate contact 19 such as W is formed so as to fill the contact holes. Next, a portion of the material film outside of the contact holes is removed by planarizing treatment, etc., for shaping into the upper portion 23b and the upper portion of the gate contact 19.

### Effect of the Fourth Embodiment

According to the fourth embodiment, when the local interconnect is formed for improving the integration degree of the circuit, the sidewall insulating films 16a and 16b are formed by a sidewall pattern transfer process and the lower portion 23a of the LI 23 is formed on the sidewall insulating film 16b, hence, it is possible to suppress the short circuit between the LI 23 and the gate electrode 4b while suppressing the number of lithography processes and the cost for fabricating the semiconductor device 400.

### Other Embodiments

It should be noted that the present invention is not intended to be limited to the above-mentioned first to fourth embodiments, and the various kinds of changes thereof can be implemented by those skilled in the art without departing from the gist of the invention.

In addition, the constituent elements of the above-mentioned embodiments can be arbitrarily combined with each other without departing from the gist of the invention.

What is claimed is:

1. A semiconductor device, comprising:
adjacent first and second transistors each formed on a semiconductor substrate, the first and second transistors respectively having first and second gate electrodes and sharing a source/drain region therebetween;
a first insulating film formed on the first gate electrode;
a second insulating film formed on the second gate electrode and comprising a region thicker than the first insulating film; and
a self-aligned contact plug connected to the source/drain region, a horizontal distance from a center position of the self-aligned contact plug to the second gate electrode being less than a horizontal distance from a center position between the first and second gate electrodes to the second gate electrode.

2. The semiconductor device according to claim 1, wherein the self-aligned contact plug is a lower portion of a local interconnect, a portion thereof is located on the second gate electrode via the second insulating film, and an upper portion of the local interconnect is formed on a region in the lower portion located above the second gate electrode.

3. The semiconductor device according to claim 2, further comprising:
a liner film comprising the same material as the first insulating film, having the substantially same thickness as the first insulating film, and covering surfaces of the first and second transistors.

4. The semiconductor device according to claim 3, wherein the self-aligned contact plug is not in contact with a portion of the first insulating film located just above the first gate electrode.

5. The semiconductor device according to claim 2, wherein the self-aligned contact plug is not in contact with a portion of the first insulating film located just above the first gate electrode.

6. The semiconductor device according to claim 1, further comprising:
a liner film comprising the same material as the first insulating film, having the substantially same thickness as the first insulating film, and covering surfaces of the first and second transistors.

7. The semiconductor device according to claim 6, wherein the self-aligned contact plug is not in contact with a portion of the first insulating film located just above the first gate electrode.

8. The semiconductor device according to claim 1, wherein the self-aligned contact plug is not in contact with a portion of the first insulating film located just above the first gate electrode.

9. A semiconductor device, comprising:
adjacent first and second transistors each formed on a semiconductor substrate, the first and second transistors respectively having first and second gate electrodes and sharing a source/drain region therebetween;
a self-aligned contact plug connected to the source/drain region; and
first and second insulating films respectively formed on the first and second gate electrodes, the first and second insulating films each having a sidewall shape in which a thickness on the self-aligned contact plug side is thicker than that on the opposite side, and the first and second insulating films sandwiching the self-aligned contact plug.

10. The semiconductor device according to claim 9, wherein the self-aligned contact plug is a lower portion of a local interconnect, a portion thereof is located on the second gate electrode via the second insulating film, and an upper portion of the local interconnect is formed on a region in the lower portion located above the second gate electrode.

11. The semiconductor device according to claim 10, further comprising:
a third transistor formed on the semiconductor substrate and having a third gate electrode, a space between the third transistor and another adjacent transistor being larger than that between the first and second transistors;
a third insulating film formed on the third gate electrode and being thinner than the first and second insulating films; and
a gate contact plug connected to an upper surface of the third gate electrode.

12. The semiconductor device according to claim 11, further comprising:
a liner film comprising the same material as the third insulating film, having the substantially same thickness as the third insulating film, and covering surfaces of the first, second and third transistors.

13. The semiconductor device according to claim 10, wherein the first insulating film has a width larger than that of the first gate electrode, and the second insulating film has a width larger than that of the second gate electrode.

14. The semiconductor device according to claim 9, further comprising:
a third transistor formed on the semiconductor substrate and having a third gate electrode, a space between the third transistor and another adjacent transistor being larger than that between the first and second transistors;
a third insulating film formed on the third gate electrode and being thinner than the first and second insulating films; and
a gate contact plug connected to an upper surface of the third gate electrode.

15. The semiconductor device according to claim 14, further comprising:
a liner film comprising the same material as the third insulating film, having the substantially same thickness as the third insulating film, and covering surfaces of the first, second and third transistors.

16. The semiconductor device according to claim 9, wherein the first insulating film has a width larger than that of the first gate electrode, and the second insulating film has a width larger than that of the second gate electrode.

17. A method of fabricating a semiconductor device, comprising:
forming adjacent first and second transistors on a semiconductor substrate, the first and second transistors respectively having first and second gate electrodes and sharing a source/drain region therebetween;
forming a first interlayer insulating film between the first and second gate electrodes;
forming a core above the first interlayer insulating film;
forming sidewall insulating films on both sides of the core so as to cover the first and second gate electrodes;
forming a second interlayer insulating film on the first interlayer insulating film and the sidewall insulating films;
forming a contact hole in the first and second interlayer insulating films so as to pass between the sidewall insulating film on the first gate electrode and that on the second gate electrode and reach the source/drain region; and
forming a self-aligned contact plug in the contact hole.

18. The method of fabricating a semiconductor device according to claim 17, wherein the self-aligned contact plug is a lower portion of a local interconnect; and
an upper portion of the local interconnect is formed on an upper surface of the self-aligned contact plug.

19. The method of fabricating a semiconductor device according to claim 18, wherein the first insulating film has a width larger than that of the first gate electrode, and the second insulating film has a width larger than that of the second gate electrode.

20. The method of fabricating a semiconductor device according to claim 17, wherein the first insulating film has a width larger than that of the first gate electrode, and the second insulating film has a width larger than that of the second gate electrode.
